(19) United States
(12) Patent Application Publication
(10) Pub. No.: US 2008/0252284 A1
(43) Pub. Date: Oct. 16, 2008

(54) Measuring a Current Supplied By a Rotating Electric Machine Such as an Alternator

(76) Inventors: Jean-Marie Pierret, Paris (FR); Raymond Rechdan, Saint Maurice (FR)

Correspondence Address: BERENATO, WHITE & STAVISH, LLC, 6550 ROCK SPRING DRIVE, SUITE 240, BETHESDA, MD, 20817, US

(21) Appl. No.: 12/089,793

(22) PCT Filed: Oct. 17, 2006
(86) PCT No.: PCT/FR2006/051045

§ 371 Date: May 28, 2008

(30) Foreign Application Priority Data
Nov. 4, 2005 (FR) 0511229

(51) Int. Cl. G01R 11/30

(52) U.S. Cl. 324/102; 324/139; 324/107

(57) ABSTRACT

The invention relates to an electric machine comprising a stator (10), a rotor (11) and a device for measuring a current in said rotating electric machine feeding electric loads (14, 15). Said device is arranged between the stator (10) and the electric loads (14, 15) in such a way that it makes it possible to measure a current (11, 12, 13, 14) running therebetween.

### TECHNICAL FIELD OF THE INVENTION

The present invention concerns the measurement of a current delivered by a rotary electrical machine, in particular an alternator or an alternator starter, in particular for managing the functioning of a motor vehicle engine.

The invention applies to all types of vehicle requiring for example engine management taking account of the torque imposed by the alternator on the engine, when there is a need for additional electrical energy.

### PRIOR ART

A rotary electrical machine, in particular an alternator, conventionally comprises:
a stator,
a rotor.

An alternator is coupled to the crankshaft of a motor vehicle engine by power transmission means such as a transmission belt. The alternator is thus driven by the engine in order to produce electrical energy so as to supply one or more batteries and the various items of electrical equipment. The battery or batteries and the electrical equipment are hereinafter referred to as electrical loads.

If these loads are brought into service, the current output by the alternator must be increased in response to their need.

The alternator will then impose on the thermal engine an additional torque liable to make the engine stall, in certain cases, if a means of controlling the engine does not enrich with fuel the mixture supplying the engine so as to maintain a sufficient speed. In general, such a control means makes it possible to better manage the functioning of the engine.

In order to improve the management of the engine, it is necessary to choose the input parameters of the control means in an optimised fashion in order to give a faithful image of the state of functioning of the alternator.

In the document WO 02/071570, the parameter received by the engine control means is a signal representing the current flowing in the excitation coil of an alternator rotor. For this purpose the document proposes a device that comprises three main parts, namely a circuit for measuring the current flowing in the rotor winding, a circuit storing the value measured and a circuit able to deliver a signal representing the level of the excitation current.

This signal is then processed by a system external to the alternator, for example a means of controlling the engine, in order to derive therefrom the current being output and the torque on the alternator. However, the control means of a vehicle using this information must have in memory the characteristics (in the form of pre-recorded values) of all the alternators that may be mounted on this vehicle, which uses a large memory size in the control means and remains an expensive task for motor manufacturers.

These manufacturers today wish for the control means to receive not a signal representing the excitation current but directly the value of the current output by the alternator. However, determining the current output by the alternator, achieved on the basis of the current flowing in the excitation winding, requires a large memory size for processing the current, incompatible with the limited memory size of the microcontrollers normally incorporated, for example, in conventional voltage regulators. This determination is in fact normally carried out from a complex table. This table must store the current output by the alternator according to its speed of rotation, the excitation current, the temperature and the battery voltage measured by the regulator.

### DISCLOSURE OF THE INVENTION

Thus a technical problem to be resolved by the object of the present invention is to propose a device for measuring an alternator current and a method of controlling this measuring device that makes it possible:
to determine the current output by the alternator while limiting the processing operations and the use of the memory in the microcontrollers,
to carry out this determination in a simple and economical fashion;
to transmit the information on the current output by the machine to a system external to the alternator.

One solution to the technical problem posed is, according to a first object of the present invention, for the current measured to be a current flowing between the stator and the electrical loads.

By virtue of the invention, information on the value of the current output by the alternator is easily obtained. In addition, a certain number of parameters, such as for example the temperature, are dispensed with.

A second object of the invention concerns a method of controlling the device for measuring a current in which a switching means, also referred to as a switch, is controlled in a first position during a time difference during which the current is measured and in that the switching means is controlled in a second position outside the time difference.

Control of the switching means thus makes it possible to limit the time during which the resistance has a current passing through it, which limits the heat dissipation. In addition, since the resistance varies little as a function of temperature, the voltage drop measured is reliable whatever the functioning of the rotary electrical machine.

Another object of the invention is a rotary electrical machine, in particular an alternator or an alternator starter, capable of supplying electrical loads, comprising:
a stator,
a rotor,
a device for measuring a current present in the rotary electrical machine supplying the electrical loads,
   characterised in that the device is placed between the output of the stator and the electrical load so as to measure a current flowing between the stator and the electrical loads.

Another object of the invention is a rotary electrical machine, in particular an alternator or an alternator starter, capable of supplying electrical loads comprising:
a stator,
a rotor,
a device for measuring a current present in the rotary electrical machine supplying the electrical loads,
   characterised in that this device comprises a resistor and in that the said device is arranged to measure a voltage drop on at least one terminal of the said resistor.

Another object of the invention is a rotary electrical machine, in particular an alternator or an alternator starter, capable of supplying electrical loads comprising:
a stator,
a rotor,
a device for measuring a current present in the rotary electrical machine supplying the electrical loads,
   characterised in that this device comprises a Hall effect sensor and in that the said device is arrange to measure the current by means of the said Hall effect sensor.

Other particularities, advantages or results of the invention will emerge from the following description given by way of example and illustrated by the accompanying figures.

### BRIEF DESCRIPTION OF THE FIGURES

FIG. 1 is an electrical diagram of the invention according to a first embodiment,

FIG. 2 is an electrical diagram of the invention according to a second embodiment,

FIG. 3 is an electrical diagram of the invention according to a third embodiment,

FIG. 4 is an electrical diagram of the invention according to a fourth embodiment,

FIG. 5 is a graphical representation for controlling the device for measuring a current according to a first method.

FIG. 6 is a graphical representation for controlling the device for measuring a current according to a second method,

FIG. 7 is a graphical representation for controlling the device for measuring a current according to a third method.

### DETAILED DESCRIPTION OF EMBODIMENTS OF THE INVENTION

In the following description, an example of a rotary electrical machine, such as an alternator for a motor vehicle, has been shown.

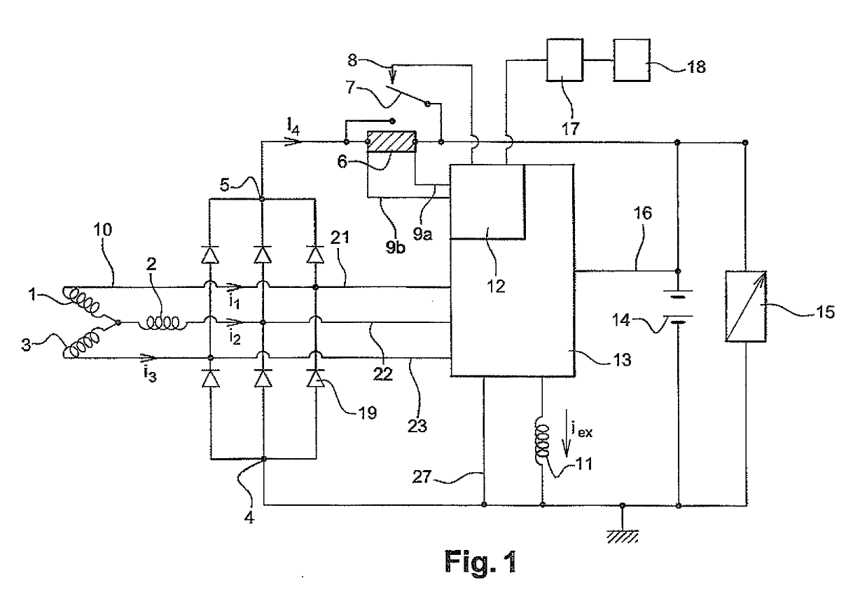

FIG. 1 depicts an alternator comprising a stator 10 or armature.

The stator is here shown with three coils offset by 120° forming the three phases 1, 2, 3 of the stator, or in a variant the number of phases may be less than or more than three.

The phases of the stator, depending on the application, are connected either in a star or in a delta.

The rotor is set in rotation by a vehicle engine 18 by means of power transmission means between the rotor and the engine, such as for example a transmission belt.

The rotor 11 or field winding creates a rotating magnetic field generating an alternating current I1, I2, I3 on each of the phases of the stator.

Each alternating current comprises positive and negative half-waves.

Each phase of the stator is connected to a pair of electronic elements 19. These elements may for example be diodes, Zener diodes or transistors. Where these switching elements are diodes, each phase is connected to the anode of a diode referred to as the positive diode and to the cathode of the other diode, referred to as the negative diode, these two diodes forming the pair of electronic elements for the phase in question.

The cathode of the positive diode is connected to the voltage of the vehicle network and the anode of the negative diodes to the system earth.

These positive and negative diodes form a current rectifying means, also referred to as a rectifier, or bridge rectifier, comprising one or more arms.

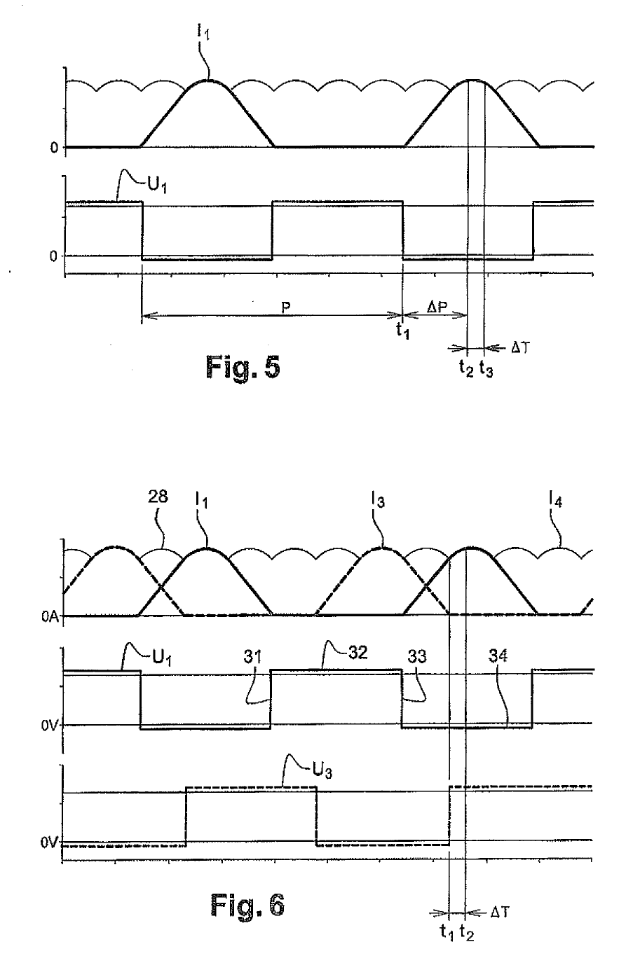

As can be seen for example in FIGS. 5, 6, 7, the voltages U1, U2, U3 present on the phases 1, 2, 3 are deformed and take the form of a square signal having low levels 34 and high levels 32 separated by rising edges 31 and failing edges 33.

The high levels are, for example, at a voltage equal to the voltage of the battery Vbat, to which there is added the junction voltage of an electronic element 19 of the rectifying means. The electronic element is for example a diode and the junction box is for example 0.8 volts.

The low levels, are, for example, at a voltage equal to the earth voltage, from which there is deducted the junction voltage of an electronic element 19 of the rectifying means.

The currents I1, I2, I3 output from the phases are smoothed by the inductances of the alternator armature and keep a substantially sinusoidal appearance. These currents output from the phases are in each of the half-arms of the rectifying means according to the conducting or non-conducting state of the electronic elements 19.

The rectification of the currents I1, I2, I3 by the rectifying means forms the current I4 delivered by the alternator.

The current I4 comprises a strong DC component allocated an alternating component of low amplitude. The alternating component is in the form of sinusoidal caps 28. The caps are formed by the tops of the substantially sinusoidal currents I1, I2, I3 present at the output of the phases.

This current I4 will supply the electrical loads, that is to say the battery or batteries 14 and the electrical equipment 15.

It should be noted that the diodes of the rectifying means also prevent the battery or batteries discharging into the windings of the stator.

The voltage of the alternator output 5 from the rectifying means increases with the speed of rotation of the rotor and therefore of the engine. However, the battery 14 cannot receive more than a certain voltage otherwise it will be destroyed by the heating of the electrolyte.

A regulator 13 will then keep constant the current present on the onboard system of the vehicle in all ranges of rotation of the engine.

For this purpose, the regulator 13 will regulate the excitation current Iex passing through the rotor 11 according to a voltage measured either at the terminals of the rectifying means or at the terminals of the battery by means of a hard-wired element 16. The choice of the voltage measured can be made according to the state of the rectifier (normal operating mode or degraded mode).

If the voltage present on the onboard system is less that a reference regulation voltage, for example 14 volts, the regulator maintains a high excitation current Iex.

When the voltage present on the onboard system exceeds the reference regulation voltage, the regulator 13 will cut the excitation current Iex in order to reduce this voltage of the onboard system.

If the voltage becomes lower than the regulation voltage, the excitation current once again increases. Then the cycle recommences.

In order to be able to effect the regulation in an appropriate manner, the regulator is connected, via a hard-wired element 27, to earth.

The torque of the alternator is dependent on the current output by the alternator, the voltage supplied by it, the speed of rotation of the rotor and the efficiency of the alternator. In order to simplify the calculations used, only equivalent continuous parameters are considered. Thus the mean value of the rectified current I4 will for example be used for calculating the torque.

This mean value will be transmitted by means of the engine control 17 for calculating this torque. In a variant, the torque can be calculated by the regulator itself, since the latter has available all the parameters and all the characteristics of the alternator.

Thus a device for measuring a current present in the alternator will measure a current flowing between the alternator stator and loads consisting for example of one or more batteries 14 and electrical equipment 15 connected to the onboard system.

A first embodiment is described and depicted in FIG. 1, in which the device measures the current I4 output 5 from the rectifying means, the rectifying means being connected to the output of the stator 10.

The measuring means comprise a resistor 6 that is placed in series with the output 5 of the rectifying means. A processing device 12 measures the voltage at the terminals of the resistor 6 that is the image of the current passing through it, by means of two hard-wired elements 9a, 9b. For this purpose the processing device is activated, for example, when it is wished to make this measurement.

The processing device 12 will then for example amplify the voltage measured and process it in order to make it useable. This voltage is then coded either in a true protocol or in the form of a duty cycle ratio and next sent to a control means 17 acting on an engine 18 of the vehicle. The engine in reaction will accelerate or slow down, which will influence the rotation of the rotor 11.

The use of a resistor makes the measurement simple and economical. In addition, since the resistance varies little as a function of temperature, the voltage drop measured is reliable.

In order to avoid an excessively great dissipation of energy due to the passage of a high current (up to 200 amperes), provision is made for the measuring means to comprise, in parallel to the resistor 6, a switching means 7 whose opening is controlled by a means 8 connected to the processing device 12.

The switching means 7 may for example be a transistor.

When the switching means 7 is open the current I4 passes through the resistor 6 and the processing device will measure the voltage drop at the terminals of this resistor.

The voltage drop is due to the passage of current I4 in the resistor 6. The processing device 12 will, according to this voltage drop, derive therefrom the mean value of the current I4.

In addition, when the switching means 7 is closed, the current I4 will pass through it, short-circuiting the resistor. This is because the switching means is less resistive than the resistance of the element 6. No measurement is then made by the processing device 12.

The switching means 7 is controlled in its first position during a time difference ΔT during which the current is measured and it is controlled in a second position outside this time difference ΔT.

The switching means 7 can be controlled in its first and second positions according to the voltage present on at least one phase. This makes it possible to adapt to the measurement according to the period P of the voltage present on at least one phase.

In a variant, the resistor 6 can be replaced by a Hall effect sensor. The sensor delivers at its output a voltage proportional to the intensity of the current passing through it. This sensor dissipates little energy. Consequently it can continuously measure the current I4 present at the output of the rectifying means of the alternator. There is therefore no switch 7 but it is the processing device, when it is activated, that determines the moment of measuring. This activation of the processing device can be effected according to the voltage present on at least one phase.

The measurement may for example be a sample of measurements, the mean value of which will be determined, to which a correction factor will be applied determined so as to define the mean value of the rectified current I4.

In a variant, the correction can be made on each measurement of the samples. Other methods of determining the mean value of a rectifying current exist, and the present description is not limited to the examples described above.

As the moment of measuring is determined according to the knowledge of at least one voltage present on at least one phase, the measurements are made in an identical part of the caps of these currents, which allows a more simple processing for obtaining the mean value of the rectified current I4.

In a variant, it is possible to measure the current output from a phase 1, 2, 3, for example in a half-arm of the rectifying means. The dimensions of the sensors are thus reduced.

This is because, in the half-arms of the rectifying means, the cross-sections of the conductors are smaller since they have passing through them only a current whose mean value is one third of the mean value of the rectified current I4.

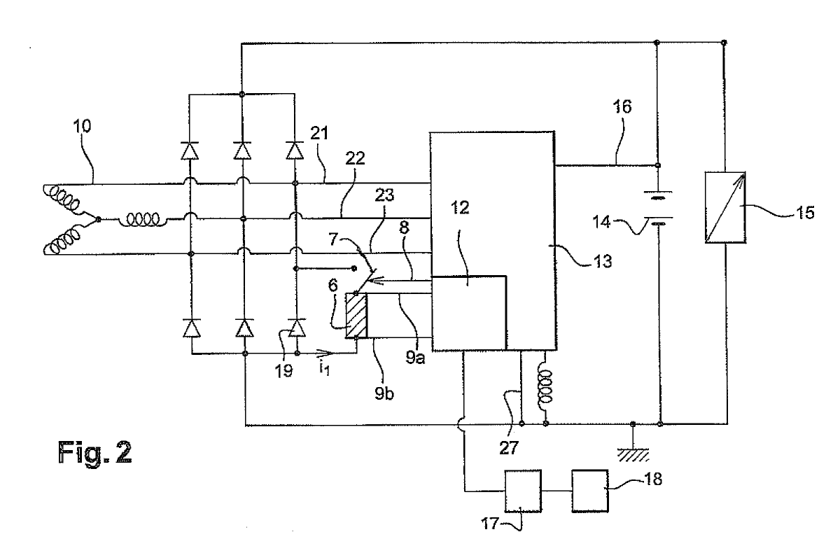

Thus, in a second embodiment depicted in FIG. 2, the current passing through a half-arm of the rectifying means is measured.

A resistor 6 and a switching means 7 are placed in parallel to the terminals of an electronic element 19, for example a diode.

The switching means 7 is controlled by the processing device 12 via the control element 8. When the switching means 7 is opened the current I1 passes through the diode. When the switch is closed the current I1 is diverted into the resistor 6, the voltage drop is then measured by the processing device 12 via the hard-wired elements 9a, 9b, 27. The hard-wired elements 9a, 9b are connected to the terminals of the resistor 6. The hard-wired element 27 connects the regulator to earth. These hard-wired elements determine the circuit portion in which the determination of the voltage drop is made. It is thus possible to measure the current on at least one terminal of the resistor 6.

If the voltage drop in the circuit portion lying between the hard-wired elements 9a and 27 is determined, it will then be necessary to take into account, in measuring the current, a line resistance inherent in the rectifying means.

If the voltage drop in the circuit portion lying between the hard-wired elements 9a and 9b is determined, that is to say directly at the terminals of the resistor 6, then account is not taken, in measuring the current, of the line resistance of the rectifying means.

The resistor 6 and the switching means 7 must be adapted so that the voltage in these two elements is less than the junction voltage of the diode 19. Thus, when the switching means 7 closes, the current I1 is diverted in the resistor 6. The switching means 7 is closed for a short time difference ΔT in order to avoid an excessively great dissipation of energy in the resistor and in order not to overflow the conduction phase of the diode 19.

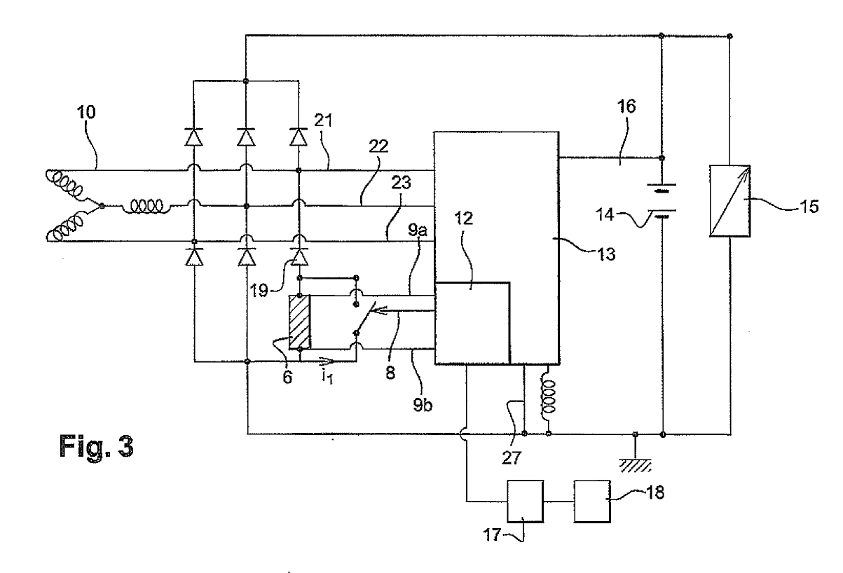

In another embodiment presented in FIG. 3, the resistor 6 is placed in series with the diode 19. A switching means 7 is in parallel with the terminals of the resistor 6.

During normal functioning of the rectifying means, the switching means 7 is closed. To measure the current, the switching means 7 opens, the current I1 is then diverted into the resistor 6 and voltage information is available for the processing device 12 via the hard-wired elements 9a, 9b, 27.

Unlike the previous embodiment, it is not necessary to choose the value of the resistor 6 according to the diode 19.

Thus it is possible to choose resistors with a higher value, the voltage drop measured is then greater, which makes it possible to use a less precise amplifier than in the embodiment in FIG. 2 in order to effect the processing.

During the passage of the current in the resistor, the processing device is activated in order to carry out the measurement and processing thereof. This processing device can be controlled as for the control of the switch 7, that is to say by analysing at least one voltage present on a phase 1, 2, 3.

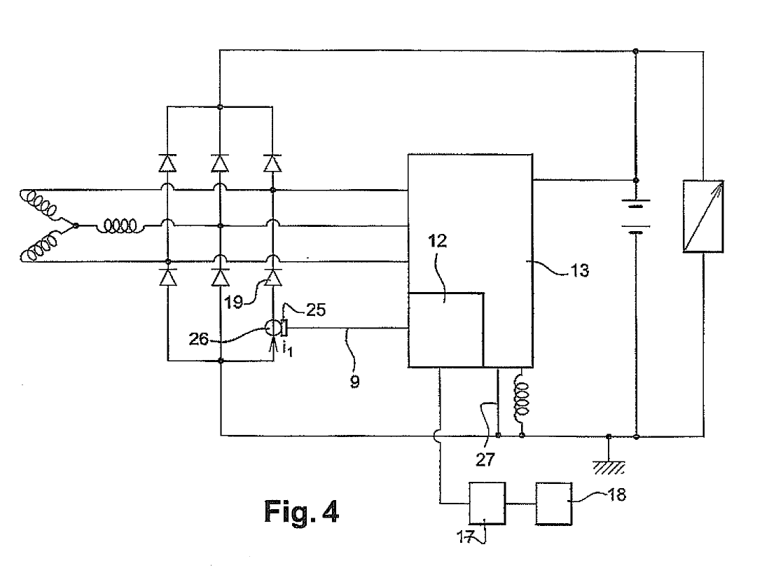

In a variant, as can be seen in FIG. 4, it is possible to use a Hall effect sensor.

The Hall effect sensor is for example mounted in the air gap of an annular magnetic circuit 26.

As the Hall effect sensor dissipates little energy, it can continuously measure the current passing through the half-arm of the rectifying means. It is however necessary for the processing device to be activated in order to carry out the measurement and processing of the current passing through the sensor. This processing device can be controlled by analysing at least one voltage present on a phase 1, 2, 3.

The measurement is next corrected by the processing device in order to determine the mean value of the rectified current I4.

In the examples presented above, the processing device 12 is integrated in the regulator 13. This makes it possible to reduce the size of the whole.

In a variant the processing device 12 can be dissociated from the regulator.

The voltage drop is determined in a circuit portion that does not comprise any electronic element 19 such as a diode, which facilitates the measurement of the current. This is because, in a diode, the resistance varies as a function of temperature, which makes it necessary to correct the value of the voltage drop as a function of this temperature. In addition, the diode is subjected to dispersion phenomena due to its manufacture, which may give rise to a variability in the measurements.

FIGS. 2, 3 show a switching means 7 present on the negative half-arm of the rectifying means between the phase and earth. This allows, in the case where the switching means is a transistor, control between 0 and 10 volts.

In a variant the voltage drop can be determined on the positive half-arm between the battery voltage and the phase. The control of the switching means 7 must then be adapted.

In all cases, it is necessary to determine the control of the switching means so that the successive measurements are carried out in the same portion of the current caps.

The switching means is controlled in a first position during a time difference ΔT during which the current is measured and the switching means 7 is controlled in a second position outside the time difference ΔT.

As can be seen in FIG. 5, a first control method consists of controlling the switching means according to the voltage present on the phase at the output of which the current is measured.

The phase voltage is for example transmitted to the regulator 13 via a hard-wired element 21, 22, 23.

The method comprises the following steps.

The regulator measures the voltage present on the phase at the output of which the current is measured.

The regulator measures a period P of the voltage present on this first phase.

The regulator detects a time interval ΔP proportional to the period P. The time interval may for example be equal to the period P divided by four.

The regulator also detects a first time t1 where the voltage present on the first phase is in a falling edge.

The switching means 7 is brought into a first position, in which the current of the first phase is measured, from a second time t2 equal to the first time t1 with the time interval ΔP added.

The switching means 7 is brought into a second position in which the current of the first phase is not measured, from a third time t3 equal to the second time t2 with a time difference ΔT added.

As can be seen in FIG. 6, a second method consists of controlling the switch according to the voltage present on at least one phase other than the phase at the output of which the current is measured.

Where the stator comprises three phases, the method comprises the following steps.

The regulator measures the voltage U3 in the third phase 3.

The regulator 13 detects a first time t1 where the voltage of the third phase is in a rising edge.

The switching means 7 is thus brought into its first position, in which the current present on the first phase is measured, as from the first time t1.

The switching means 7 is brought into its second position, in which the current is not measured, as from a second time t2 equal to the first time t1 with a time difference ΔT added.

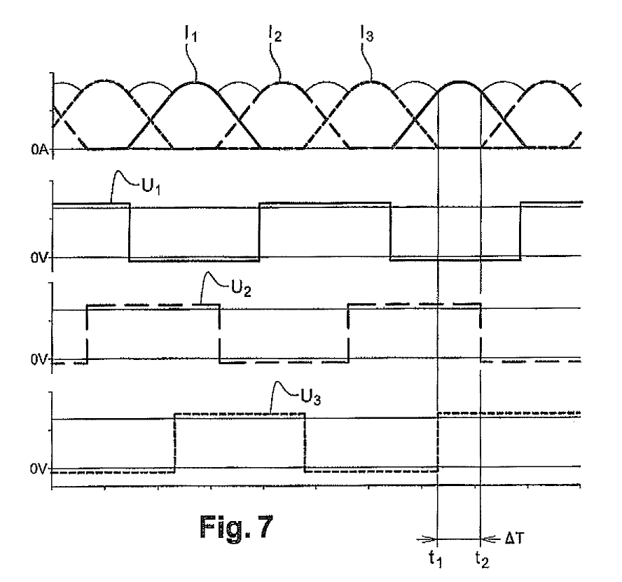

As can be seen in FIG. 7, a third method consists of using the voltage information of a second phase and a third phase of the stator in order to effect the measurement on the current present at the output of the first phase.

To this end, the regulator measures the voltage U2 in the second phase 2.

The regulator measures the voltage U3 in the third phase 3.

The regulator detects a first time t1 where the voltage U3 of the third phase is merged with the voltage U2 of the second phase 2 on its high level.

The switching means 7 is then brought into its first position, in which the current of the first phase is measured, as from the first time t1.

The switching means 7 is brought into its second position, in which the current is not measured in the first phase as from a second time t2. The second time t2 is for example detected when the voltage U2 of the second phase 2 is no longer merged with the voltage U3 of the third phase 3 on its high level.

The time difference ΔT, between times t1 and t2, corresponds to the difference between the rising edge of the phase 3 and the falling edge of the phase 2. This difference corresponds substantially to the duration of a rectifying cap. It is therefore possible to more easily determine the mean value of the rectified current.

This makes the measurement more precise.

In the various methods, the time difference ΔT is less than the period P divided by two of a voltage present on a phase. Advantageously, the time difference ΔT is less than a period divided by six. The time difference ΔT is for example around a few tens of microseconds.

It will be noted that the voltages present on the various phases have the same period P.

The invention thus makes it possible, through measuring a current flowing between the stator and the electrical loads 14, 15, to determine the torque of the alternator in real time during the functioning of the rotary electrical machine.

The present description is not limited to the example embodiments described above, in particular it has been described in the context of an alternator but is applicable to a rotary electrical machine such as an alternator starter or an electromagnetic retarder.

The stator, the rotor and the measuring device are placed in a common enclosure.

In a variant, the measuring device is placed in a box distinct from the enclosure in which the stator and rotor are disposed, the box being in particular connected to this enclosure by an electrical connection.

1. Rotary electrical machine, in particular an alternator or an alternator starter, capable of supplying electrical loads, comprising:
a stator (10),
a rotor (11),
a device for measuring a current present in the rotary electrical machine supplying the electrical loads (14, 15),
characterised in that the device is placed between the output of the stator (10) and the electrical loads (14, 15) so as to measure a current (I1, I2, I3, I4) flowing between the stator and the electrical loads (14, 15).

2. Machine according to claim 1, characterised in that it comprised a current rectifier connected at the output of the stator and in that the device is placed between the output of the current rectifier and the electrical loads (14, 15) so as to measure the current (I4) at the output (5) of the rectifier.

3. Machine according to claim 1, characterised in that the stator (10) comprises one or more phases and in that the device is placed in a half-arm of the rectifier so as to measure a current (I1, I2, I3) at the output of a phase (1, 2, 3).

4. Machine according to claim 1, characterised in that the device comprises a resistor (6).

5. Machine according to claim 1, characterised in that the device is arranged to measure the current on at least one terminal of the resistor (6).

6. Machine according to claim 5, characterised in that the device is arranged to measure the current on the two terminals of the resistor (6).

7. Machine according to claim 6, characterised in that the device comprises a switch (7).

8. Machine according to claim 1, characterised in that the device comprises a Hall effect sensor (26).

9. Device for measuring a current for a rotary electrical machine according to claim 1, characterised in that the said device is placed between the output of the stator (10) and the electrical loads (14, 15) so as to measure a current (I1, I2, I3, I4) flowing between the stator and the electrical loads (14, 15).

10. Method of controlling the device for measuring a current of a rotary electrical machine according to claim 7, characterised in that the switch (7) is controlled in a first position during a time difference (ΔT) during which the current is measured and in that the switch (7) is controlled in a second position outside the time difference (ΔT).

11. Control method according to claim 10, characterised in that the current is measured at the output (5) of the rectifier.

12. Control method according to claim 10, characterised in that the switch (7) is controlled according to the voltage present on at least one phase.

13. Control method according to claim 10, characterised in that the current is measured at the output of a phase (1, 2, 3) of the stator.

14. Control method according to claim 13, characterised in that the switch (7) is controlled according to the voltage present on the phase at the output of which the current is measured.

15. Control method according to claim 13, characterised in that the stator (10) comprises several phases (1, 2, 3) and in that the switch (7) is controlled in its first position according to the voltage present on at least one phase other than the phase at the output of which the current is measured.

16. Control method according to claim 14, characterised in that it comprises the following steps:
the regulator measures a voltage (U1) present on a first phase (1),
the regulator measures a period (P) of the voltage present on the phase (1),
the regulator calculators a time interval (ΔT) proportional to the period (P),
the regulator detects a first time (t1) where the voltage present on the phase (1) is in a falling edge,
the switch (7) is brought into its first position, as from a second time (t2) equal to the first time (t1) with the time interval (ΔP) added,
the switch (7) is brought into its second position, as from a third time (t3) equal to the second time (t2) with the time difference (ΔT) added.

17. Control method according to claim 16, characterised in that the time interval (ΔP) is equal to the period (P) divided by four.

18. Control method according to claim 15, characterised in that the stator (10) comprises three phases (1, 2, 3) and in that the current (I1) is measured at the output of the first phase (1), the method comprising the following steps:
the regulator measures the voltage (U3) of the third phase (3),
the regulator detects a first time (t1) where the voltage of the third phase is in a rising edge,
the switch (7) is brought into its first position as from the first time (t1),
the switch (7) is brought into its second position as from a second time (t2) equal to the first time (t1) with the time difference (ΔT) added.

19. Control method according to claim 15, characterised in that the stator (10) comprises three phases (1, 2, 3) and in that the current (I1) is measured at the output of the first phase (1), the method comprising the following steps:
the regulator measures the voltage (U2) of the second phase (2),
the regulator measures the voltage (U3) of the third phase (3),
the regulator detects a first time (t1) where the voltage (U3) of the third phase is merged with the voltage (U2) of the second phase (2) on its high level,
the switch (7) is brought into its first position as from the first time (t1),
the switch (7) is brought into its second position as from a second time (t2) equal to the first time (t1) with the time difference (ΔT) added.

20. Control method according to claim 19, characterised in that the second time (t2) is detected when the voltage (U2) of the second phase is no longer merged with the voltage (U3) of the third phase (3).

21. Control method according to claim 10, characterised in that the time difference (ΔT) is less than the period (P) divided by two of a voltage present on a phase.

22. Rotary electrical machine, in particular an alternator or an alternator starter, capable of supplying electrical loads comprising:
a stator (10),
a rotor (11),
a device for measuring a current present in the rotary electrical machine supplying the electrical loads (14, 15),
characterised in that the device comprises a resistor (6) and in that the said device is arranged to measure a voltage drop on at least one terminal of the said resistor (6).

23. Rotary electrical machine, in particular an alternator or an alternator starter, capable of supplying electrical loads comprising:
a stator (10),
a rotor (11),
a device for measuring a current present in the rotary electrical machine supplying the electrical loads (14, 15),
characterised in that this device comprises a Hall effect sensor (26) and in that the said device is arrange to measure the current by means of the said Hall effect sensor (26).
